(19) United States
(12) Patent Application Publication
(10) Pub. No.: US 2025/0047058 A1
(43) Pub. Date: Feb. 6, 2025

(54) OPTOELECTRONIC SEMICONDUCTOR COMPONENT AND METHOD FOR PRODUCING A PLURALITY OF OPTOELECTRONIC SEMICONDUCTOR COMPONENTS

(71) Applicant: ams-OSRAM International GmbH, Regensburg (DE)

(72) Inventors: Stephan BERGHOFER, Pettendorf (DE); Jan SEIDENFADEN, Neumarkt I.D Oberpfalz (DE); Markus RICHTER, Burglengenfeld (DE); Nicole BERNER, Walderbach (DE)

(73) Assignee: ams-OSRAM International GmbH, Regensburg (DE)

(21) Appl. No.: 18/717,306

(22) PCT Filed: Nov. 16, 2022
(86) PCT No.: PCT/EP2022/082089

§ 371 Date: Jun. 6, 2024

(30) Foreign Application Priority Data
Dec. 8, 2021 (DE) 10 2021 132 299.5

(51) Int. Cl. H01S 5/02251; H01S 5/02

(52) U.S. Cl. CPC H01S 5/02251; H01S 5/0201

(57) ABSTRACT

The invention relates to an optoelectronic semiconductor component having a frame body, which is radiolucent at least in regions, and at least one first semiconductor chip which is designed to emit a first electromagnetic radiation. The frame body has a recess. At least a first waveguide is formed in the frame body. A first coupling surface of the first waveguide is formed on a side surface of the recess facing the first semiconductor chip. A decoupling surface is formed on an outer surface of the frame body. The first semiconductor chip is arranged in the recess in such a way that at least a part of the first electromagnetic radiation enters into the first waveguide. The invention also relates to method for producing a plurality of optoelectronic semiconductor components.

### CROSS-REFERENCE TO RELATED APPLICATIONS

The present application is a national stage entry from International Application No. PCT/EP2022/082089, filed on Nov. 16, 2022, published as International Publication No. WO 2023/104454 A1 on Jun. 15, 2023, and claims priority to German Patent Application No. 10 2021 132 299.5, filed Dec. 8, 2021, the disclosures of all of which are hereby incorporated by reference in their entireties.

### FIELD

An optoelectronic semiconductor component and a method for producing a plurality of optoelectronic semiconductor components are disclosed.

### BACKGROUND

The optoelectronic semiconductor component is in particular configured to generate and/or detect electromagnetic radiation, for example in the infrared or ultraviolet spectral range and preferably light that is perceptible to the human eye.

One task to be solved is to specify an optoelectronic semiconductor component which enables simplified production.

A further task to be solved is to specify a method for the simplified production of a plurality of optoelectronic semiconductor components.

These tasks are solved, inter alia, by an optoelectronic semiconductor component and a method for producing a plurality of optoelectronic semiconductor components with the features of the independent patent claims. Preferred further embodiments are the subject of the dependent patent claims.

The semiconductor component is in particular configured to emit coherent electromagnetic radiation.

### SUMMARY

According to at least one embodiment, the optoelectronic semiconductor component comprises a frame body that is at least sectionally radiation permeable and at least a first semiconductor chip that is configured to emit a first electromagnetic radiation. For example, the semiconductor chip comprises an active region. In particular, the active region has a pn junction, a double heterostructure, a single quantum well structure (SQW) or a multiple quantum well structure (MQW) for the generation of radiation or for radiation detection. The semiconductor chip is, for example, a photodiode or a luminescence diode, in particular a light-emitting diode. Preferably, the semiconductor chip is a laser diode. In particular, the semiconductor chip is configured to generate coherent radiation. A laser diode advantageously has a high luminance.

Preferably, the frame body is at least sectionally transparent, in particular transparent to electromagnetic radiation generated or to be detected during operation of the semiconductor chip. For example, the frame body is formed at least sectionally with one of the following materials: Si, SiO₂, polymer. Furthermore, the frame body may at least sectionally comprise an opaque material, in particular a material that is impermeable to radiation.

The frame body is used, for example, to protect the semiconductor chip from external environmental influences. In particular, the frame body is mechanically self-supporting and provides the optoelectronic semiconductor component with mechanical stability. The frame body shows traces of a separation process, for example.

In particular, the frame body has a top side and a bottom side opposite the top side. In particular, the top side is connected to the bottom side via several side surfaces. A main extension plane of the frame body preferably runs parallel to the top side and/or the bottom side of the frame body. In particular, the traces of a separation process, for example a sawing process or a stealth dicing process, are recognizable on the side surfaces of the frame body.

According to at least one embodiment of the optoelectronic semiconductor component, the frame body has a recess. The recess extends, for example, from the top of the frame body into the frame body. In particular, the recess has side surfaces. Furthermore, the recess may have a bottom surface.

The side surfaces of the recess are advantageously aligned transversely, in particular perpendicular to the bottom surface of the recess and/or the bottom side of the frame body. For example, the side surfaces are aligned oblique to the bottom surface. Advantageously, this enables particularly simple manufacture.

According to at least one embodiment of the optoelectronic semiconductor component, at least a first waveguide is formed in the frame body. In particular, the waveguide comprises a core region which has a higher refractive index than a material surrounding the core region. For example, the first waveguide is a hollow-core waveguide. Furthermore, the first waveguide comprises a first input coupling area and an output coupling area. Electromagnetic radiation, for example, enters the waveguide via the first input coupling area.

Electromagnetic radiation exits the waveguide via the output coupling area, for example. Electromagnetic radiation preferably propagates along a main extension direction of the waveguide.

According to at least one embodiment of the optoelectronic semiconductor component, a first input coupling area of the first waveguide is formed on a side surface of the recess facing the semiconductor chip. In particular, the input coupling area enables electromagnetic radiation generated in the recess to enter the waveguide.

According to at least one embodiment of the optoelectronic semiconductor component, an output coupling area is formed on an outer surface of the frame body. Preferably, the outer surface is a surface delimiting a lateral extension of the frame body. The outer surface of the frame body includes, among other things, the top side, the bottom side and the side surfaces of the frame body. In particular, electromagnetic radiation can emerge from the frame body via the output coupling area.

According to at least one embodiment of the optoelectronic semiconductor component, the first semiconductor chip is arranged in the recess such that at least a portion of the first electromagnetic radiation enters the first waveguide.

In other words, the radiation exit surface of the first semiconductor chip is aligned with the coupling area of the first waveguide. Advantageously, electromagnetic radiation of the first semiconductor chip can thus be guided via the first waveguide to an outer surface of the frame body.

According to at least one embodiment, the optoelectronic semiconductor component comprises,
a frame body which is at least sectionally radiation permeable and at least one first semiconductor chip which is configured to emit a first electromagnetic radiation, wherein
the frame body has a recess,
at least one first waveguide is formed in the frame body,
a first input coupling area of the first waveguide is formed on a side surface of the recess facing the semiconductor chip,
an output coupling area is formed on an outer surface of the frame body,
the first semiconductor chip is arranged in the recess in such a way that at least part of the first electromagnetic radiation enters the first waveguide.

An optoelectronic semiconductor component described here is based, among other things, on the following considerations: In order to produce a plurality of optoelectronic semiconductor components, it is advantageous to process several semiconductor components in parallel. This includes steps for manufacturing and processing the semiconductor components as well as steps for their electro-optical characterization.

The optoelectronic semiconductor component described here makes use, among other things, of the idea of forming optoelectronic semiconductor components in a substrate which is at least sectionally radiation permeable in such a way that a plurality of semiconductor components can be produced in parallel and subsequently characterized electro-optically. In particular, a main waveguide is provided in the substrate for this purpose, which allows the electromagnetic radiation emitted by several individual semiconductor components to emerge from the substrate at a single output coupling area. Advantageously, this allows electro-optical characterization of a plurality of semiconductor components at a single output coupling area. Repeated alignment of a detector for each semiconductor component can thus be advantageously avoided.

The substrate can then be singulated into a plurality of optoelectronic semiconductor components, each with a frame body.

According to at least one embodiment of the optoelectronic semiconductor component, the frame body comprises a transmission region and an opaque region. In particular, the transmission region is formed with a material that differs from the opaque region. The transmission region is translucent, in particular transparent to electromagnetic radiation generated in the optoelectronic semiconductor component during operation. The opaque region is opaque, in particular impermeable to electromagnetic radiation generated in the optoelectronic semiconductor component during operation.

Preferably, the transmission region extends in a lateral direction from the recess to a side surface of the frame body. For example, the transmission region extends from a first side surface of the frame body to a second side surface of the frame body opposite the first side surface.

Preferably, the transmission region is arranged on a side of the frame body facing the input coupling area of the first waveguide. In particular, the opaque region is arranged on a side of the frame body extending transversely to the input coupling area of the first waveguide and on a side of the frame body opposite the input coupling area of the first waveguide. The opaque region thereby reduces or prevents, for example, undesired output coupling of electromagnetic radiation in a direction opposite to the output coupling direction of the semiconductor chip.

According to at least one embodiment of the optoelectronic semiconductor component, the frame body is formed entirely with a radiation permeable material. This simplifies manufacture, as the entire frame body is advantageously formed with the same material.

According to at least one embodiment of the optoelectronic semiconductor component, the first waveguide extends completely within the frame body. In other words, the first waveguide is embedded in the material of the frame body along its main direction of extension. Advantageously, the first waveguide is thus particularly well protected from external environmental influences, such as mechanical damage.

According to at least one embodiment of the optoelectronic semiconductor component, the frame body completely surrounds the at least one semiconductor chip laterally. Preferably, the frame body completely surrounds all semiconductor chips laterally. In particular, the frame body protects the semiconductor chips from mechanical damage and provides the optoelectronic semiconductor component with greater mechanical stability.

According to at least one embodiment of the optoelectronic semiconductor component, the frame body projects vertically beyond the at least one semiconductor chip. Preferably, the frame body projects vertically beyond all semiconductor chips. This makes it particularly easy to mount a cover element. For example, the cover element completely closes the recess. Advantageously, a protective atmosphere can thus be set up in the recess to protect the semiconductor chips from harmful gases.

According to at least one embodiment of the optoelectronic semiconductor component, the recess completely penetrates the frame body. Preferably, this simplifies mounting of a semiconductor chip through the recess, for example on a carrier arranged underneath. In other words, the recess of the frame body in particular has no bottom surface. A bottom surface of the recess is formed, for example, by the carrier.

According to at least one embodiment, the optoelectronic semiconductor component comprises a second semiconductor chip and a second waveguide, wherein the second semiconductor chip emits a second electromagnetic radiation and is arranged in the recess such that at least a portion of the second electromagnetic radiation enters the second waveguide.

Preferably, the first waveguide and the second waveguide are brought close together at their output coupling areas. In other words, the output coupling area of the first waveguide is arranged in particular directly next to the output coupling area of the second waveguide. In particular, the output coupling areas of the waveguides are arranged at a distance of between 50 μm and 5 μm, preferably between 25 μm and 10 μm, from one another.

The second electromagnetic radiation has, for example, a main wavelength that differs from a main wavelength of the first electromagnetic radiation. A main wavelength is to be understood here and in the following as a wavelength at which a spectrum of an electromagnetic radiation has a global maximum. In other words, the first electromagnetic radiation has in particular a different color than the second electromagnetic radiation.

The second waveguide preferably extends completely within the frame body. In other words, the second waveguide is embedded in the material of the frame body along its main direction of extension. Advantageously, the second waveguide is thus particularly well protected from external environmental influences, such as mechanical damage.

According to at least one embodiment, the optoelectronic semiconductor component comprises a main waveguide in which the first electromagnetic radiation and the second electromagnetic radiation are superimposed. The main waveguide preferably extends completely within the frame body. In other words, the main waveguide is embedded in the material of the frame body along its main direction of extension. Advantageously, the main waveguide is thus particularly well protected against external environmental influences, such as mechanical damage. In particular, the main waveguide comprises an output coupling area.

The output coupling area of the main waveguide is formed, for example, on an outer surface of the frame body. Preferably, the output coupling area is formed on a side surface or an upper side of the frame body. Alternatively, the output coupling area of the main waveguide can also be formed inside the frame body. The first electromagnetic radiation and the second electromagnetic radiation are superimposed on each other in the main waveguide and are thus particularly well mixed. In particular, the first electromagnetic radiation and the second electromagnetic radiation are coupled out of the optoelectronic semiconductor component together through the output coupling area of the main waveguide.

According to at least one embodiment of the optoelectronic semiconductor component, the main waveguide ends at a side surface of the frame body. Consequently, the output coupling area of the main waveguide is formed on a side surface of the frame body. Advantageously, electromagnetic radiation coupled into the main waveguide can thus be coupled out to the side of the frame body.

According to at least one embodiment of the optoelectronic semiconductor component, the main waveguide extends from a first side of the frame body to an opposite second side of the frame body. In particular, the main waveguide extends transversely, preferably perpendicular to the first and second sides of the frame body. Consequently, the main waveguide has two surfaces that are adjacent to a side surface of the frame body. Preferably, only one of these surfaces is used as an output coupling area. Such a configuration of the main waveguide facilitates its production.

According to at least one embodiment of the optoelectronic semiconductor component, the main waveguide ends at an upper side of the frame body. Advantageously, such an orientation of the main waveguide enables the output coupling area to be formed on the upper side of the frame body.

A method for producing a plurality of optoelectronic semiconductor components is further disclosed. In particular, the optoelectronic component can be manufactured by means of a method described herein. That is, all features disclosed in connection with the method for producing a plurality of optoelectronic semiconductor components are also disclosed for the optoelectronic semiconductor component and vice versa.

According to at least one embodiment, the method comprises introducing a plurality of recesses into a substrate that is at least sectionally radiation permeable. The at least sectionally radiation permeable substrate is preferably formed with a glass. In particular, the substrate also comprises opaque, in particular radiation-impermeable areas.

Preferably, the opaque regions shield unwanted scattered radiation. The recesses are produced using an etching process, for example.

According to at least one embodiment, the method comprises forming a plurality of first waveguides and a main waveguide in the substrate, wherein a respective input coupling area of a first waveguide is formed on a side surface of a recess and electromagnetic radiation emerges from the main waveguide towards an outer surface of the substrate. In particular, the waveguides are formed in a transmission region of the substrate. For example, the first waveguides are formed in the substrate by means of a focused laser beam.

Alternatively, the waveguides can be formed by means of ion implantation. The electromagnetic radiation emerging from an outer surface of the substrate can be detected, for example, for electro-optical characterization of semiconductor chips arranged inside the substrate.

According to at least one embodiment, the method comprises arranging a respective first semiconductor chip, which is configured to emit a first electromagnetic radiation, in a respective recess, wherein each first semiconductor chip is arranged in its associated recess in such a way that at least a portion of the first electromagnetic radiation enters the first waveguide. A radiation exit surface of the first semiconductor chips is consequently aligned in each case with an input coupling area of a first waveguide. In particular, the recesses penetrate the substrate completely. For example, the semiconductor chips are arranged on a carrier arranged under the substrate in the recesses of the substrate.

According to at least one embodiment, the method comprises singulating the substrate to produce a plurality of optoelectronic semiconductor components. For example, the substrate is cut between two recesses in each case.

Singulation of the substrate produces, in particular, a plurality of optoelectronic semiconductor components, each with a frame body that is at least sectionally radiation permeable.

In other words, the frame bodies of the optoelectronic semiconductor components are formed continuously before the singulation step, for example as part of the radiation permeable substrate. After the singulation step into a plurality of optoelectronic semiconductor components along first separation lines, the result is in particular a plurality of optoelectronic semiconductor components each with a frame body. Consequently, the frame bodies are preferably formed with the material of the substrate. In particular, the finished optoelectronic semiconductor components show traces of a separation process. For example, traces of a separation process, in particular a sawing process or a stealth dicing process, are visible on the side surfaces of the optoelectronic semiconductor components.

According to at least one embodiment, the method comprises the following steps:
A) introducing a plurality of recesses into a substrate that is at least sectionally radiation permeable,
B) forming a plurality of first waveguides in the substrate, wherein
in each case an input coupling area of a first waveguide is formed on a side surface of a recess,
electromagnetic radiation emerges from the first waveguides in the direction of an outer surface of the substrate,
C) arranging a respective first semiconductor chip, which is configured to emit a first electromagnetic radiation, in a respective recess, wherein
each first semiconductor chip is arranged in its associated recess in such a way that at least part of the first electromagnetic radiation enters the first waveguide, and
D) singulating the substrate to produce a plurality of optoelectronic semiconductor components.

Preferably, the process steps are carried out in their alphabetical order.

According to at least one embodiment of the method, an electro-optical characterization of the first semiconductor chips is carried out. For an electro-optical characterization and/or an active alignment of the semiconductor chips, the first electromagnetic radiation emitted by the first semiconductor chips is detected and analyzed by a detector, for example.

According to at least one embodiment of the method, an electro-optical characterization of all first semiconductor chips is carried out before the singulation step.

Advantageously, the electro-optical characterization can thus be carried out while the semiconductor components are still connected. This simplifies the positioning of a detector.

According to at least one embodiment of the method, a plurality of first waveguides is brought together in a main waveguide. In particular, the main waveguide is formed in the substrate in step B). Preferably, electromagnetic radiation emerges from the main waveguide in the direction of an outer surface of the substrate.

The main waveguide advantageously extends to a side surface of the substrate. Electro-optical characterization of several first semiconductor chips can advantageously be performed with a single positioning of a detector on an output coupling area of the main waveguide. Repositioning of the detector for each first semiconductor chip can thus be advantageously omitted.

According to at least one embodiment of the method, a second semiconductor chip, which is configured to emit a second electromagnetic radiation, is arranged in a recess in each case, each second semiconductor chip being arranged in its associated recess in such a way that at least some of the second electromagnetic radiation enters a second waveguide.

Preferably, the first and second semiconductor chips are aligned as a function of the positions of the first and second waveguides.

Alternatively, the first and/or second semiconductor chips can be mounted before the first and/or second waveguides are inserted, so that the first and/or second waveguides are aligned according to the positions of the first and/or second semiconductor chips.

According to at least one embodiment of the method, an electro-optical characterization of the first semiconductor chips and the second semiconductor chips is carried out using the electromagnetic radiation emerging at the output coupling area. Advantageously, an electro-optical characterization of a plurality of first and second semiconductor chips can thus be carried out, whereby a detector only has to be positioned once at the output coupling area.

According to at least one embodiment of the method, an output coupling area of the substrate is formed on a side surface of the substrate. Advantageously, electromagnetic radiation coupled into the main waveguide can thus be coupled out to the side of the substrate. This makes it particularly easy to detect the electromagnetic radiation from a detector.

According to at least one embodiment of the method, a first portion of the substrate is provided prior to step A), the first waveguides and the second waveguides are applied to a surface of the first portion of the substrate in step A), and then a second portion of the substrate is arranged on the first portion of the substrate. Preferably, an imaginary separation plane between the first portion and the second portion of the substrate corresponds to a plane parallel to a main extension direction of the substrate. For example, the waveguides are vapor-deposited on the first portion of the substrate and, in particular, provided with a further protective layer before the second portion of the substrate is applied.

In particular, the substrate is provided in two separate steps. For example, the waveguides are applied to the first portion of the substrate using a photolithographic method. Alternatively, the waveguides can be vapor-deposited onto the first portion of the substrate and then provided with a protective layer. The waveguides are embedded in the substrate by the arrangement of the second portion of the substrate.

According to at least one embodiment of the method, at least one output coupling area of the substrate is formed on a top surface of the substrate. Advantageously, such an arrangement enables output coupling in a direction perpendicular to the main extension direction of the substrate. A detector for electro-optical characterization of the semiconductor chips can thus be positioned and moved parallel to a main extension plane of the substrate in order to characterize each semiconductor chip.

According to at least one embodiment of the method, an electro-optical characterization of all semiconductor chips is carried out before the singulation step. Advantageously, all semiconductor chips of all subsequent semiconductor components on a substrate can thus be characterized electro-optically even before singulation. Due to the contiguous substrate, the plurality of semiconductor chips in the recesses is easy to handle and positioning of a detector for electro-optical characterization is simplified.

An optoelectronic semiconductor component described herein is particularly suitable for use as a high-power light source for application in motor vehicle headlights or projection lighting.

Further advantages and advantageous configurations and further embodiments of the optoelectronic semiconductor component result from the following exemplary embodiments shown in connection with the figures.

### BRIEF DESCRIPTION OF THE DRAWINGS

FIG. 1 a schematic top view of an optoelectronic semiconductor component described herein according to a first exemplary embodiment,

FIG. 2 a schematic top view of an optoelectronic semiconductor component described herein according to a second exemplary embodiment,

FIG. 3 a schematic top view of an optoelectronic semiconductor component described herein according to a third exemplary embodiment,

FIG. 4 a schematic top view of a plurality of optoelectronic semiconductor components described herein according to a fourth exemplary embodiment before a step for their singulation,

FIG. 5 a schematic top view of a plurality of optoelectronic semiconductor components described herein according to a fifth exemplary embodiment before a step for their singulation,

FIG. 6A a schematic top view of an optoelectronic semiconductor component described herein according to a sixth exemplary embodiment,

FIG. 6B a schematic sectional view of the optoelectronic semiconductor component described herein according to the sixth exemplary embodiment along a section at the first cutting line AA shown in FIG. 6A,

FIG. 7A a schematic top view of an optoelectronic semiconductor component described herein according to a seventh embodiment,

FIG. 7B a schematic sectional view of the optoelectronic semiconductor component described herein according to the seventh exemplary embodiment along a section at the second cutting line BB shown in FIG. 7A,

FIG. 8 a schematic top view of a plurality of optoelectronic semiconductor components described herein according to an eighth embodiment prior to a step for their singulation, and

FIG. 9 a schematic top view of an optoelectronic semiconductor component described herein according to a ninth exemplary embodiment.

### DETAILED DESCRIPTION

Elements that are identical, similar or have the same effect are marked with the same reference signs in the figures. The figures and the proportions of the elements shown in the figures are not to be regarded as being to scale. Rather, individual elements may be shown in exaggerated size for better visualization and/or better comprehensibility.

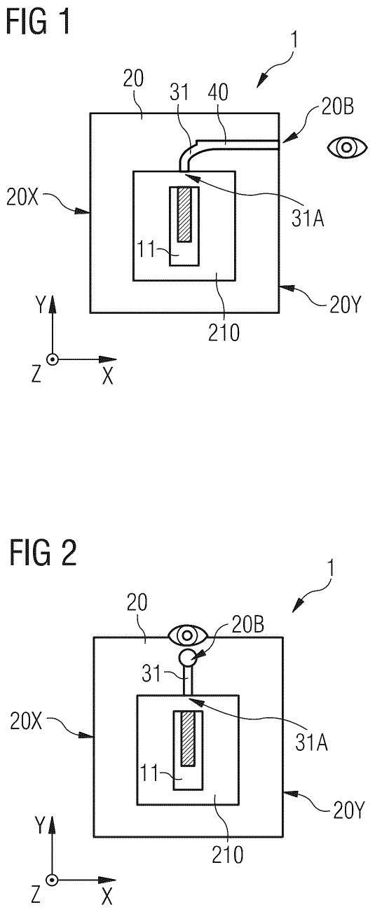

FIG. 1 shows a schematic top view of an optoelectronic semiconductor component 1 described here according to a first exemplary embodiment.

The optoelectronic semiconductor component 1 comprises a frame body 20 formed with a radiation permeable material. The lateral expansion of the frame body 20 is delimited by side surfaces. The lateral expansion is to be understood here and in the following figures as an expansion in the first lateral direction X and the second lateral direction Y.

The frame body 20 comprises a first side surface 20X and a second side surface 20Y opposite the first side surface 20X.

Furthermore, the frame body is delimited in its vertical extension by a bottom side and a top side. A vertical expansion is to be understood here and in the following figures as an expansion in the vertical direction Z. The side surfaces of the frame body 20 have traces of a separation process.

The frame body 20 includes a recess 210 that completely penetrates the frame body in a vertical direction Z. A first waveguide 31 and a main waveguide 40 are embedded in the frame body 20. Furthermore, a first semiconductor chip 11 is arranged in the recess 210 of the frame body 20, which is arranged to emit a first electromagnetic radiation. For example, the first semiconductor chip 11 is a light-emitting diode or a laser chip configured to emit coherent electromagnetic radiation.

The first waveguide 31 has an input coupling area on a side surface of the recess 210. The first semiconductor chip 11 is arranged in the recess 210 such that at least a portion of the first electromagnetic radiation enters the first waveguide 31.

The first waveguide 31 is coupled to the main waveguide 40. Consequently, the electromagnetic radiation coupled into the first waveguide 31 is coupled into the main waveguide 40. The main waveguide 40 extends to an outer surface of the frame body 20. The main waveguide 40 forms an output coupling area 20B on a side surface of the frame body 20.

The first electromagnetic radiation coupled into the first waveguide 31 consequently emerges from the output coupling area 20B from the frame body 20. There, the first electromagnetic radiation can be detected, for example, by a detector. The detector is shown here and in the following figures by a symbol in the shape of an eye.

FIG. 2 shows a schematic top view of an optoelectronic semiconductor component 1 described here according to a second exemplary embodiment. The second exemplary embodiment shown in FIG. 2 essentially corresponds to the first exemplary embodiment shown in FIG. 1.

In contrast to the first exemplary embodiment, the main waveguide 40 according to the second exemplary embodiment is aligned with an upper side of the frame body 20.

Consequently, the output coupling area 20B is arranged on the upper side of the frame body 20.

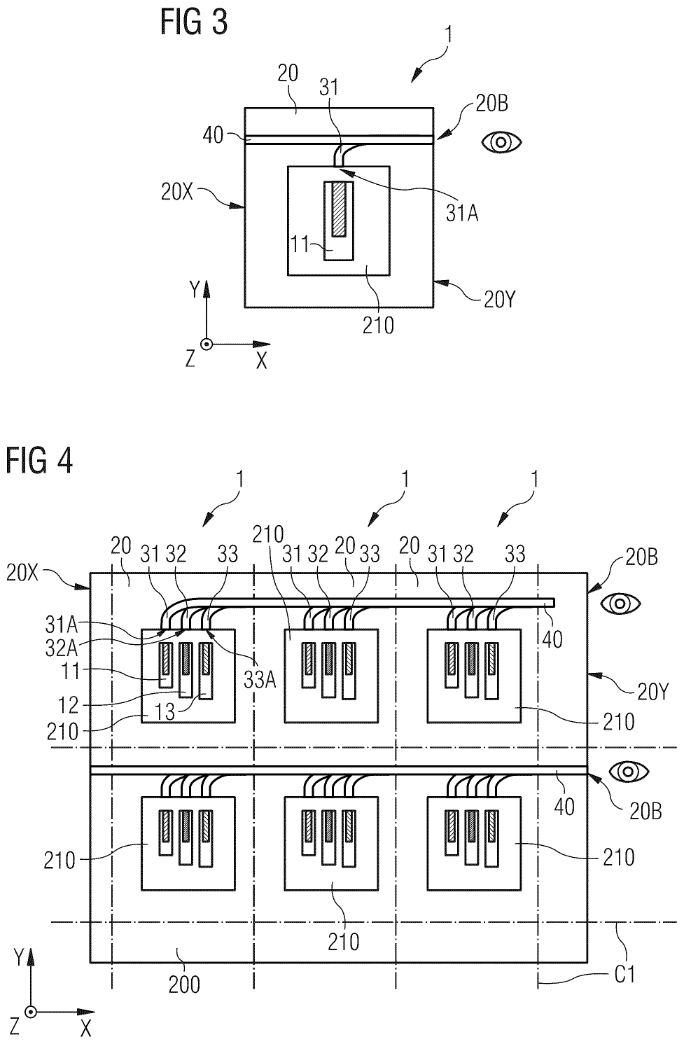

FIG. 3 shows a schematic top view of an optoelectronic semiconductor component described herein according to a third exemplary embodiment. The third exemplary embodiment shown in FIG. 3 essentially corresponds to the first exemplary embodiment shown in FIG. 1.

In contrast to the first exemplary embodiment, the main waveguide 40 according to the third exemplary embodiment extends from the first side surface 20X to the second side surface 20Y of the frame body 20. An output coupling area 20B is arranged on the second side surface 20Y. Such an embodiment of the main waveguide 40 enables, in particular, a simplified production of the main waveguide 40.

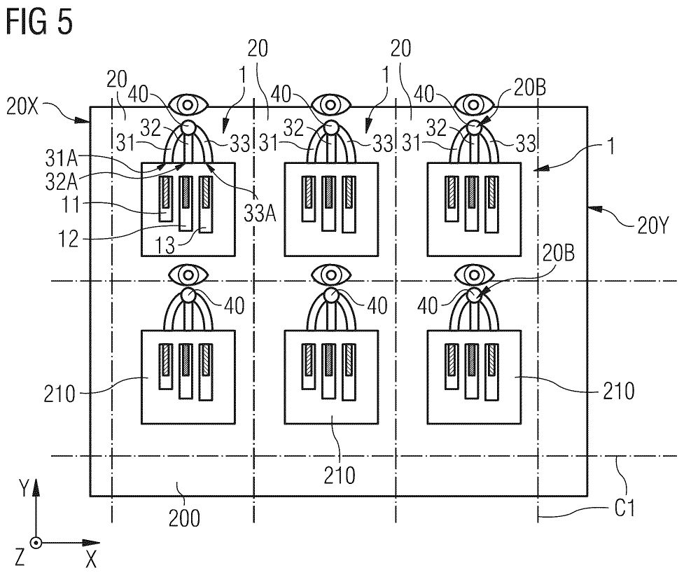

FIG. 4 shows a schematic top view of a plurality of optoelectronic semiconductor components 1 described herein according to a fourth exemplary embodiment prior to a step for their singulation. The optoelectronic semiconductor components 1 are shown in a continuous, radiation permeable substrate 200. The subsequent separation lines are represented by dashed first separation lines C1.

The semiconductor components 1 essentially correspond in each case to the first exemplary embodiment shown in FIG. 1. In addition, the semiconductor components 1 each comprise a second semiconductor chip 12 and a third semiconductor chip 13. The second semiconductor chip 12 is configured to emit a second electromagnetic radiation and the third semiconductor chip 13 is configured to generate a third electromagnetic radiation. Preferably, the first electromagnetic radiation is a main wavelength in the red spectral range, the second electromagnetic radiation is a main wavelength in the green spectral range and the third electromagnetic radiation is a main wavelength in the blue spectral range.

Each optoelectronic semiconductor component 1 comprises a first waveguide 31 having a first input coupling area 31A, a second waveguide 32 having a second input coupling area 32A and a third waveguide 33 having a third input coupling area 33A. The first electromagnetic radiation is coupled into the first waveguide 31 via the first input coupling area 31A, the second electromagnetic radiation is coupled into the second waveguide 32 via the second input coupling area 32A and the third electromagnetic radiation is coupled into the third waveguide 33 via the third input coupling area 33A.

The frame bodies 20 of the optoelectronic semiconductor components 1 are formed continuously as part of the radiation permeable substrate 200 before the singulation step. After the singulation step into a plurality of optoelectronic semiconductor components 1 along the dashed first separation lines C1, a plurality of optoelectronic semiconductor components 1 each having a frame body 20 is obtained. The frame bodies 20 are consequently formed with the material of the substrate 200. In particular, the finished optoelectronic semiconductor components 1 have traces of a separation process. For example, traces of a separation process, in particular a sawing process or a stealth dicing process, are visible on side surfaces of the optoelectronic semiconductor components 1.

The first waveguides 31, the second waveguides 32 and the third waveguides 33 are connected to a main waveguide 40. For example, the main waveguide 40 extends laterally completely across the substrate 200 from a first side surface 20X to an output coupling area 20B on a second side surface 20Y opposite the first side surface 20X, as shown in the bottom row of semiconductor components 1 in FIG. 4. Alternatively, the main waveguide 40 extends only within the substrate 200 and terminates still within the lateral extent of the substrate 200, as shown in the row of the semiconductor components 1 in FIG. 4.

The electromagnetic radiation coupled into the main waveguide 40 leaves the substrate 200 through an output coupling area 20B on an outer surface of the substrate 200.

At the output coupling area 20B, the first, the second and the third electromagnetic radiation from all first, second and third semiconductor chips 11, 12, 13 of all optoelectronic semiconductor components 1 of a row can be detected by means of a detector. Advantageously, all first, second and third semiconductor chips 11, 12, 13 of all optoelectronic semiconductor components 1 arranged side by side in a row can thus be characterized electro-optically without changing a position of the detector.

FIG. 5 shows a schematic top view of a plurality of optoelectronic semiconductor components described herein according to a fifth exemplary embodiment prior to a step for their singulation. The fifth exemplary embodiment shown in FIG. 5 essentially corresponds to the fourth exemplary embodiment shown in FIG. 4.

In contrast to the fourth exemplary embodiment, the main waveguides 40 according to the second exemplary embodiment are each aligned with a top side of the substrate 200.

Consequently, the output coupling areas 20B are arranged on the upper side of the substrate 200. The first waveguides 31, the second waveguides 32 and the third waveguides 33 of each subsequent semiconductor component 1 are each combined in a main waveguide 40. Thus, each first semiconductor chip 11, each second semiconductor chip 12 and each third semiconductor chip 13 of each semiconductor component 1 can be electro-optically characterized from a respective position on the top surface of the substrate 200.

Preferably, electro-optical characterization of the semiconductor chips 11, 12, 13 is performed while the optoelectronic semiconductor components 1 are interconnected in the substrate 200. This facilitates the positioning of a detector.

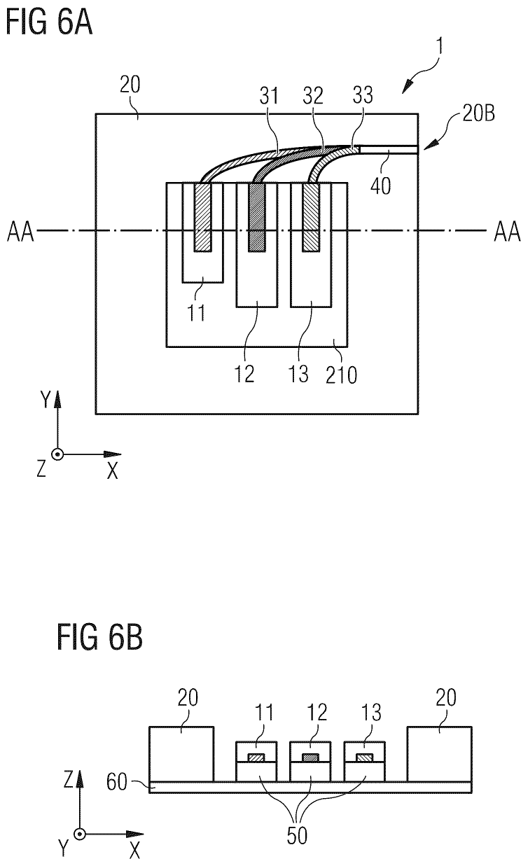

FIG. 6A shows a schematic top view of an optoelectronic semiconductor component described herein according to a sixth exemplary embodiment. The sixth exemplary embodiment shown in FIG. 6A essentially corresponds to the first exemplary embodiment shown in FIG. 1.

In contrast to the first exemplary embodiment, in addition to a first semiconductor chip 11, a second semiconductor chip 12 and a third semiconductor chip 13 are also arranged in the recess 210 of the frame body 20. The first semiconductor chip 11 emits a first electromagnetic radiation, the second semiconductor chip 12 emits a second electromagnetic radiation and the third semiconductor chip 13 emits a third electromagnetic radiation. The first electromagnetic radiation has a main wavelength in the red spectral range, the second electromagnetic radiation has a main wavelength in the green spectral range and the third electromagnetic radiation has a main wavelength in the blue spectral range.

A first waveguide 31, a second waveguide 32, a third waveguide 33 and a main waveguide 40 are embedded in the frame body 20. The first, second and third waveguides 31, 32, 33 are superimposed on each other in the main waveguide 40. The main waveguide 40 extends to a side surface of the frame body 20. The first, second and third electromagnetic radiations emerge from an output coupling area 20B from the frame body 20.

FIG. 6B shows a schematic sectional view of the optoelectronic semiconductor component described herein according to the sixth exemplary embodiment along a section at the first cutting line AA shown in FIG. 6A. In the sectional view, it can be seen that the semiconductor chips 11, 12, 13 are each arranged on a mounting body 50. The mounting body 50 is formed, for example, with an electrically and thermally conductive material. Preferably, the mounting bodies 50 are each used for the electrical connection and cooling of a semiconductor chip 11, 12, 13. The frame body 20 and the first, second and third semiconductor chips 11, 12, 13 are arranged on a common carrier 60. The common carrier 60 is mechanically self-supporting. The expansion of the frame body 20 in the vertical direction Z is greater than the expansion of the first, second and third semiconductor chips 11, 12, 13 in the vertical direction Z. In other words, the frame body 20 projects beyond the semiconductor chips 11, 12, 13 in the vertical direction Z.

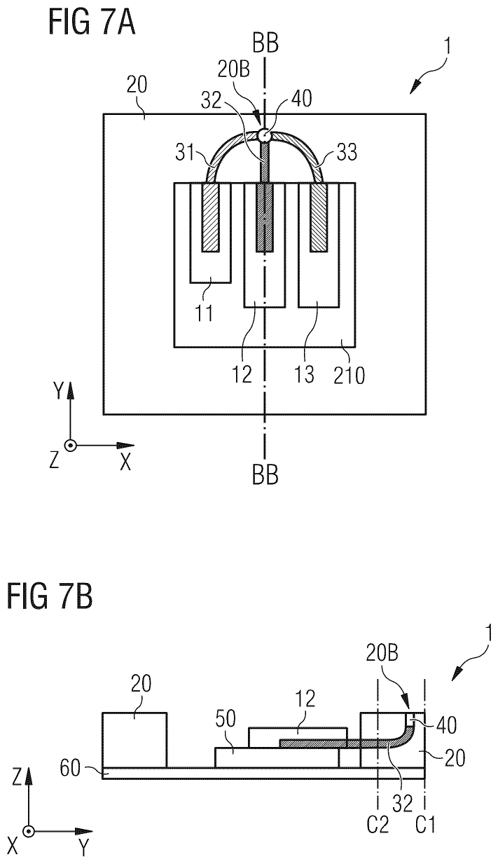

FIG. 7A shows a schematic top view of an optoelectronic semiconductor component described herein according to a seventh exemplary embodiment. The seventh exemplary embodiment shown in FIG. 7A essentially corresponds to the sixth exemplary embodiment shown in FIG. 6A.

In contrast to the sixth exemplary embodiment, the main waveguide 40 is aligned with a top side of the frame body 20. Consequently, the output coupling area 20B is arranged on the top side of the frame body 20. The first waveguide 31, second waveguide 32 and third waveguide 33 of the semiconductor component 1 are combined in the main waveguide 40. Thus, the first semiconductor chip 11, the second semiconductor chip 12 and the third semiconductor chip 13 of the semiconductor component 1 can be electro-optically characterized from a position on the top side of the frame body 20.

FIG. 7B shows a schematic sectional view of the optoelectronic semiconductor component described herein according to the seventh exemplary embodiment along a section at the second cutting line BB shown in FIG. 7A. In the sectional view, the course of the second waveguide 32 and the main waveguide 40 in the vertical direction Z is recognizable. The second waveguide 32 has a curvature, whereby a deflection of the second electromagnetic radiation can be achieved. After an electro-optical characterization of the semiconductor chips 11, 12, 13 by means of a detector at the output coupling area 20B, the frame body 20 can be cut to size.

For example, the frame body 20 may be cut at the first separation line C1, thereby retaining the curvature of the waveguides 31, 32, 33 and the main waveguide 40 with the output coupling area 20B at the top of the frame body 20.

Alternatively, the frame body 20 can be cut at a second separation line C2, whereby the part of the waveguides 31, 32, 33 curved towards the top of the frame body 20 and the main waveguide 40 are separated and output coupling of the first, second and third electromagnetic radiation to a side surface of the frame body 20 takes place. Other positions of a separation line and shapes of the first, second and third waveguides 31, 32, 33 are also conceivable in order to achieve a desired output coupling direction in the finished optoelectronic semiconductor component 1.

Preferably, the first, second, third and main waveguides with such a shape are generated by a laser beam in the frame body 20.

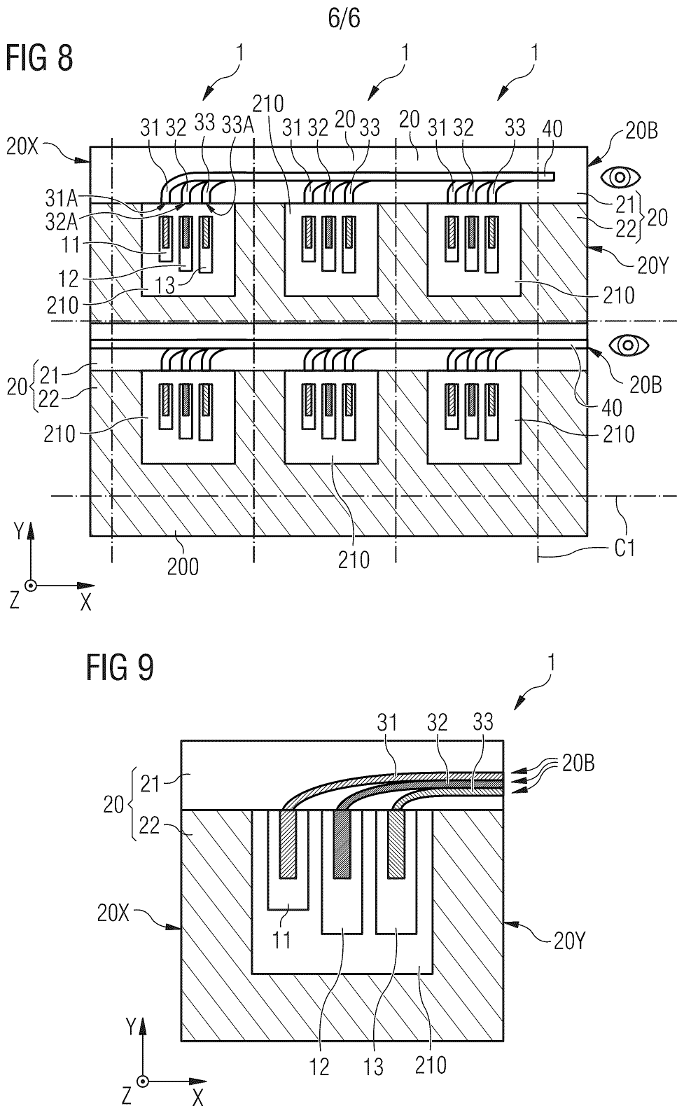

FIG. 8 shows a schematic top view of a plurality of optoelectronic semiconductor components 1 described here according to the eighth exemplary embodiment before a step for their singulation. The eighth exemplary embodiment shown in FIG. 8 essentially corresponds to the fourth exemplary embodiment shown in FIG. 4.

In contrast to the fourth exemplary embodiment, the substrate 200 is formed with radiation-permeable material and with opaque, in particular radiation-impermeable material. Opaque regions 22 of the frame body 20 are formed from the opaque material after singulation and transmission regions 21 of the frame body 20 are formed from the radiation permeable material after singulation. The radiation permeable material is formed, for example, with a glass. The opaque material is formed, for example, with a dark mold material, in particular a polymer. Preferably, the substrate 200 is formed continuously. The waveguides 31, 32, 33 are formed in the radiation permeable material forming the transmission regions 21.

FIG. 9 shows a schematic top view of an optoelectronic semiconductor component 1 described herein according to the ninth exemplary embodiment. The ninth exemplary embodiment shown in FIG. 9 essentially corresponds to the sixth exemplary embodiment shown in FIG. 6A.

In contrast to the sixth exemplary embodiment, the first, second and third waveguides 31, 32, 33 are individually guided up to a side surface of the frame body 20. Output coupling areas 20B for each of the first, second and third waveguides 31, 32, 33 are formed on the side surface of the frame body 20. The output coupling areas 20B of the waveguides 31, 32, 33 are arranged in particular at a distance of between 50 μm and 5 μm, preferably between 25 μm and 10 μm from one another. Advantageously, a main waveguide 40 can thus be dispensed with. Furthermore, the frame body 20 comprises a radiation-permeable transmission region 21 and a radiation-impermeable opaque region 22. The transmission region 21 extends from the recess 210 to a side surface of the frame body 20. Furthermore, the transmission region 21 extends from a first side surface 20X of the frame body 20 to a second side surface 20Y opposite the first side surface 20X. The waveguides 31, 32, 33 are formed in the radiation permeable material forming the transmission region 21.

The invention is not limited by the description based on the embodiments. Rather, the invention includes any new feature as well as any combination of features, which includes in particular any combination of features in the patent claims, even if this feature or combination itself is not explicitly stated in the patent claims or embodiments.

1. An optoelectronic semiconductor component comprising a frame body which is at least sectionally radiation permeable and at least one first semiconductor chip which is configured to emit a first electromagnetic radiation, wherein
the frame body has a recess,
at least one first waveguide is formed in the frame body,
a first input coupling area of the first waveguide is formed on a side surface of the recess facing the first semiconductor chip,
an output coupling area is formed on an outer surface of the frame body,
the first semiconductor chip is arranged in the recess in such a way that at least a portion of the first electromagnetic radiation enters the first waveguide.

2. The optoelectronic semiconductor component according to claim 1, wherein the frame body comprises a transmission region and an opaque region.

3. The optoelectronic semiconductor component according to claim 1, wherein the first waveguide extends completely within the frame body.

4. The optoelectronic semiconductor component according to claim 1, wherein the frame body completely surrounds the at least one semiconductor chip laterally.

5. The optoelectronic semiconductor component according to claim 1, wherein the frame body projects vertically beyond the at least one semiconductor chip.

6. The optoelectronic semiconductor component according to claim 1, wherein the recess completely penetrates the frame body.

7. The optoelectronic semiconductor component according to claim 6, which comprises a second semiconductor chip and a second waveguide, wherein
the second semiconductor chip emits a second electromagnetic radiation and is
arranged in the recess in such a way that at least a part of the second electromagnetic radiation enters the second waveguide.

8. The optoelectronic semiconductor component according to claim 7, which
comprises a main waveguide, in which
the first electromagnetic radiation and the second electromagnetic radiation are superimposed on each other.

9. The optoelectronic semiconductor component according to claim 6, wherein the main waveguide ends at a side surface of the frame body.

10. The optoelectronic semiconductor component according to claim 9, in which the main waveguide extends from a first side of the frame body to an opposite second side of the frame body.

11. The optoelectronic semiconductor component according to claim 6, in which the main waveguide ends at an upper side of the frame body.

12. A method for producing a plurality of optoelectronic semiconductor components comprising:
A) introducing a plurality of recesses into a substrate which is at least sectionally radiation permeable,
B) forming a plurality of first waveguides in the substrate, wherein
in each case, an input coupling area of a first waveguide is formed on a side surface of a recess,
electromagnetic radiation emerges from the first waveguide towards an outer surface of the substrate,
C) arranging a respective first semiconductor chip, which is configured to emit a first electromagnetic radiation, in a respective recess, wherein
each first semiconductor chip is arranged in its associated recess in such a way that at least part of the first electromagnetic radiation enters the first waveguide, and
D) singulating the substrate to produce a plurality of optoelectronic semiconductor components.

13. The method for producing a plurality of optoelectronic semiconductor components according to claim 12, wherein an electro-optical characterization of the first semiconductor chips is carried out.

14. The method for producing a plurality of optoelectronic semiconductor components according to claim 12, wherein
an electro-optical characterization of all first semiconductor chips is carried out before singulation step D.

15. The method for producing a plurality of optoelectronic semiconductor components according to claim 12, wherein
a plurality of first waveguides are brought together in a main waveguide.

16. The method for producing a plurality of optoelectronic semiconductor components according to claim 12, wherein
a second semiconductor chip, which is configured to emit a second electromagnetic radiation, is arranged in a recess in each case, wherein
each second semiconductor chip is arranged in its associated recess in such a way that at least part of the second electromagnetic radiation enters a second waveguide.

17. The method for producing a plurality of optoelectronic semiconductor components according to claim 16, wherein
an electro-optical characterization of the first semiconductor chips and the second semiconductor chips is carried out on the basis of the electromagnetic radiation emerging at the output coupling area.

18. The method for producing a plurality of optoelectronic semiconductor components according to claim 12, wherein
an output coupling area of the substrate is formed on a side surface of the substrate.

19. The method for producing a plurality of optoelectronic semiconductor components according to am claim 15, wherein
a first portion of the substrate is provided before step A,
the first waveguides and the second waveguides are arranged on a surface of the first portion of the substrate in the step A, and
then a second portion of the substrate is arranged on the first portion of the substrate.

20. The method for producing a plurality of optoelectronic semiconductor components according to claim 12, wherein
at least one output coupling area of the substrate is formed on an upper surface of the substrate.
